(19) United States
(12) Patent Application Publication
(10) Pub. No.: US 2007/0222489 A1
(43) Pub. Date: Sep. 27, 2007

(54) VOLTAGE-CONTROLLED OSCILLATOR AND ADJUSTMENT CIRCUIT FOR VOLTAGE-CON TROLLED OSCILLATOR

(75) Inventor: Shouhei Kousai, Tokyo (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/691,050

(22) Filed: Mar. 26, 2007

(30) Foreign Application Priority Data
Mar. 27, 2006 (JP) 2006-85575

(51) Int. Cl. H03L 7/06

(52) U.S. Cl. 327/156

(57) ABSTRACT

A voltage-controlled oscillator, has a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with an oscillation frequency controlling voltage; a first MOS transistor connected between the other end of said first inductor and a ground potential and having the gate connected to the other end of said second inductor; a second MOS transistor connected between the other end of said second inductor and said ground potential and having the gate connected to the other end of said first inductor; a third inductor having one end connected to said power supply potential; a third MOS transistor connected between the other end of said third inductor and said ground potential and having the gate connected to the gate of the first MOS transistor; a fourth inductor having one end connected to said power supply potential; a fourth MOS transistor connected between the other end of said fourth inductor and said ground potential and having the gate connected to the gate of the second MOS transistor; and a second variable capacitor connected between the other end of said third inductor and the other end of said fourth inductor.

### CROSS-REFERENCE TO RELATED APPLICATIONS

This application is based upon and claims the benefit of priority from the prior Japanese Patent Application No. 2006-85575, filed on Mar. 27, 2006, the entire contents of which are incorporated herein by reference.

### BACKGROUND OF THE INVENTION

1. Field of the Invention

The present invention relates to a voltage-controlled oscillator that outputs an oscillation signal at a desired oscillation frequency, and an adjustment circuit provided with the voltage-controlled oscillator.

2. Background Art

For example, mobile communication terminals, whose market is rapidly growing, each have to provide a voltage-controlled oscillator (VCO) mounted thereon.

Among other characteristics of the voltage-controlled oscillator, the oscillation frequency and the frequency variation range are important.

For example, a conventional voltage-controlled oscillator has: a tank circuit that has a first inductor having one end connected to a power supply potential, a second inductor having one end connected to the power supply potential, and a variable capacitor connected between the other end of the first inductor and the other end of the second inductor and having a capacitance controlled in accordance with an oscillation frequency controlling voltage; a first bipolar transistor connected between the other end of the first inductor and a ground potential and having the base connected to the second inductor; a second bipolar transistor connected between the other end of the second inductor and the ground potential and having the base connected to the other end of the first inductor; a third inductor having one end connected to the power supply potential; a third bipolar transistor connected between the other end of the third inductor and the ground potential and having the base connected to the base of the first bipolar transistor; a fourth inductor having one end connected to the power supply potential; and a fourth bipolar transistor connected between the other end of the fourth inductor and the ground potential and having the base connected to the base of the second bipolar transistor.

This voltage-controlled oscillator controls the oscillation frequency of the oscillation signal from the tank circuit and expands the frequency variation range by producing mutual impedances on the first and second inductors of the tank circuit by the action of the third and fourth bipolar transistors and the third and fourth inductors (see Japanese Patent Laid-Open Publication No. 2001-313527).

However, in the conventional voltage-controlled oscillator, the current flowing through the first inductor and the current flowing through the fourth inductor are out of phase because the currents flow through the variable capacitor.

Thus, the conventional voltage-controlled oscillator has a problem that a sufficient mutual impedance cannot be produced, and a desired frequency variation range cannot be provided.

### SUMMARY OF THE INVENTION

According one aspect of the present invention, there is provided: a voltage-controlled oscillator, comprising a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with an oscillation frequency controlling voltage; a first MOS transistor connected between the other end of said first inductor and a ground potential and having the gate connected to the other end of said second inductor; a second MOS transistor connected between the other end of said second inductor and said ground potential and having the gate connected to-the other end of said first inductor; a third inductor having one end connected to said power supply potential; a third MOS transistor connected between the other end of said third inductor and said ground potential and having the gate connected to the gate of the first MOS transistor; a fourth inductor having one end connected to said power supply potential; a fourth MOS transistor connected between the other end of said fourth inductor and said ground potential and having the gate connected to the gate of the second MOS transistor; and a second variable capacitor connected between the other end of said third inductor and the other end of said fourth inductor.

According another aspect of the present invention, there is provided: a voltage-controlled oscillator, comprising a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with an oscillation frequency controlling voltage; a first MOS transistor connected between the other end of said first inductor and a ground potential and having the gate connected to the other end of said second inductor; a second MOS transistor connected between the other end of said second inductor and said ground potential and having the gate connected to the other end of said first inductor; a third inductor having one end connected to one output end of said tank circuit; a fourth inductor having one end connected to the other end of said third inductor and the other end connected to the other output end of the tank circuit; and a second variable capacitor connected between the one end of said third inductor and the other end of said fourth inductor.

According further aspect of the present invention, there is provided: an adjustment circuit for a voltage-controlled oscillator, comprising a voltage-controlled oscillator including: a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with a first oscillation frequency controlling voltage; a first MOS transistor connected between the other end of said first inductor and a ground potential and having the gate connected to the other end of said second inductor; a second MOS transistor connected between the other end of said second inductor and said ground potential and having the gate connected to the other end of said first inductor; a third inductor having one end connected to said power supply potential; a third MOS transistor connected between the other end of said third inductor and said ground potential and having the gate connected to the gate of the first MOS transistor; a fourth inductor having one end connected to said power supply potential; a fourth MOS transistor connected between the other end of said fourth inductor and said ground potential and having the gate connected to the gate of the second MOS transistor; and a second variable capacitor connected between the other end of said third inductor and the other end of said fourth inductor and having a capacitance controlled in accordance with a second oscillation frequency controlling voltage; an amplitude controlling section that detects the amplitude of an oscillation signal from said tank circuit and controls the amplitude of the oscillation signal from said tank circuit by changing an operating current for operating said voltage-controlled oscillator; a current detecting section that detects said operating current; and a control circuit that controls said amplitude controlling section and said voltage-controlled oscillator, wherein said control circuit controls said amplitude controlling section to change said operating current at a desired amplitude in accordance with the value of the current detected by said current detecting section, detects the oscillation frequency of the oscillation signal from said tank circuit and controls said first and second oscillation frequency controlling voltages to change the values of the capacitance of the first and second variable capacitors, thereby making said tank circuit output an oscillation signal at a desired oscillation frequency.

According still further aspect of the present invention, there is provided: an adjustment circuit for a voltage-controlled oscillator, comprising a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with a first oscillation frequency controlling voltage; a first MOS transistor connected between the other end of said first inductor and a ground potential and having the gate connected to the other end of said second inductor; a second MOS transistor connected between the other end of said second inductor and said ground potential and having the gate connected to the other end of said first inductor; a third inductor having one end connected to one output end of said tank circuit; a fourth inductor having one end connected to the other end of said third inductor and the other end connected to the other output end of the tank circuit; and a second variable capacitor connected between the one end of said third inductor and the other end of said fourth inductor and having a capacitance controlled in accordance with a second oscillation frequency controlling voltage; an amplitude controlling section that detects the amplitude of an oscillation signal from said tank circuit and controls the amplitude of the oscillation signal from said tank circuit by changing an operating current for operating said voltage-controlled oscillator; a current detecting section that detects said operating current; and a control circuit that controls said amplitude controlling section and said voltage-controlled oscillator, wherein said control circuit controls said amplitude controlling section to change said operating current at a desired amplitude in accordance with the value of the current detected by said current detecting section, detects the oscillation frequency of the oscillation signal from said tank circuit and controls said first and second oscillation frequency controlling voltages to change the values of the capacitance of the first and second variable capacitors, thereby making said tank circuit output an oscillation signal at a desired oscillation frequency.

### BRIEF DESCRIPTION OF THE DRAWINGS

FIG. 1 is a circuit diagram showing a circuit configuration of a voltage-controlled oscillator 100 according to an embodiment 1 of the present invention, which is an aspect of the present invention;

FIGS. 2 is a vector diagram for illustrating a relationship between the current flowing through the voltage-controlled oscillator 100 according to the embodiment 1 of the present invention and the voltage applied to the same;

FIG. 3 is a vector diagram for illustrating a relationship between the current flowing through the voltage-controlled oscillator 100 according to the embodiment 1 of the present invention and the voltage applied to the same;

FIG. 4 is a vector diagram for illustrating a relationship between the current flowing through the voltage-controlled oscillator 100 according to the embodiment 1 of the present invention and the voltage applied to the same;

FIG. 5 is a circuit diagram showing essential parts of a voltage-controlled oscillator 200 according to the embodiment 2 of the present invention, which is an aspect of the present invention; and

FIG. 6 is a circuit diagram showing essential parts of an adjustment circuit 300 for a voltage-controlled oscillator according to the embodiment 3 of the present invention, which is an aspect of the present invention.

### DETAILED DESCRIPTION

In the following, embodiments of the present invention will be described with reference to the drawings.

### Embodiment 1

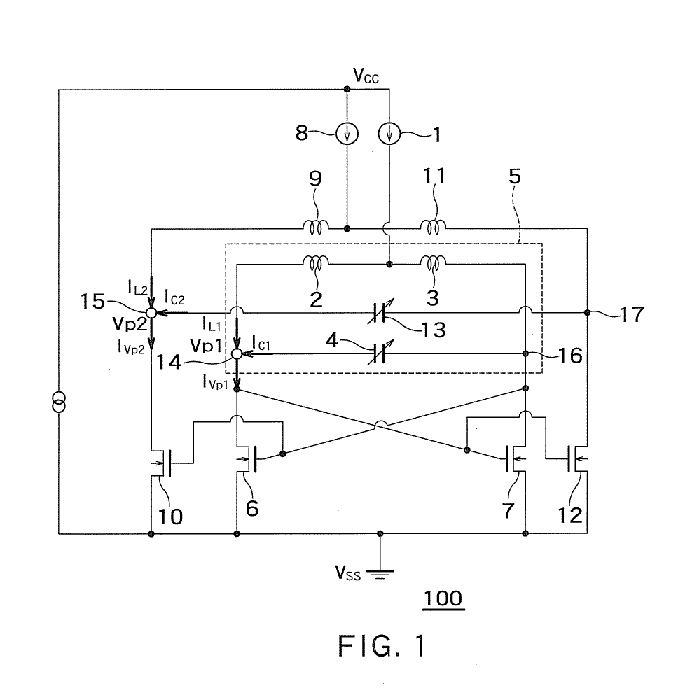

FIG. 1 is a circuit diagram showing a circuit configuration of a voltage-controlled oscillator 100 according to an embodiment 1 of the present invention.

As shown in FIG. 1, the voltage-controlled oscillator 100 has a tank circuit 5 including a first inductor 2 that has one end connected to a power supply potential “V_{CC}” via a first current source 1, a second inductor 3 that has one end connected to the power supply potential “V_{CC}” via the first current source 1, and a first variable capacitor 4 that is connected between the other end of the first inductor 2 and the other end of the second inductor 3 and has a capacitance controlled in accordance with a first oscillation frequency controlling voltage.

In addition, the voltage-controlled oscillator 100 has a first n-type MOS transistor 6 that is connected between the other end of the first inductor 2 and a ground potential “V_{SS}” and has the gate connected to the other end of the second inductor 3 and a second n-type MOS transistor 7 that is connected between the other end of the second inductor 3 and the ground potential “V_{SS}” and has the gate connected to the other end of the first inductor 2.

In addition, the voltage-controlled oscillator 100 has a third inductor 9 that has one end connected to the power supply potential “V_{CC}” via a second current source 8, a third MOS transistor 10 that is connected between the other end of the third inductor 9 and the ground potential “V_{SS}” and has the gate connected to the gate of the first MOS transistor 6, a fourth inductor 11 that has one end connected to the power supply potential “V_{CC}”, a fourth MOS transistor 12 that is connected between the other end of the fourth inductor 11 and the ground potential “V_{SS}” and has the gate connected to the gate of the second MOS transistor 7, and a second variable capacitor 13 that is connected between the other end of the third inductor 9 and the other end of the fourth inductor 11 and has a capacitance controlled in accordance with a second oscillation frequency controlling voltage.

When an operating current flows, the first inductor 2 and the third inductor 9 produce a mutual inductance. Similarly, when an operating current flows, the second inductor 3 and the fourth inductor 11 produce a mutual inductance in accordance with the phase of the operating current.

For example, the first variable capacitor 4 is composed of two MOS transistors that share the back gate, the source and the drain (the gates of the transistors constitute the opposite ends of the first variable capacitor, respectively), and the capacitance of the first variable capacitor 4 is changed by controlling the oscillation frequency controlling voltage applied to the back gate, the source and the drain.

The tank circuit 5 changes the oscillation frequency of the oscillation signal when the capacitance of the first variable capacitor 4 changes with the oscillation frequency controlling voltage applied thereto. Besides, the oscillation frequency changes with the mutual inductances described above.

It should be noticed that the third and fourth MOS transistors 10 and 12 do not have to be biased.

Now, a principle of control of the oscillation frequency of the voltage-controlled oscillator 100 configured as described above will be described.

FIGS. 2 to 4 are vector diagrams for illustrating a relationship between the current flowing through the voltage-controlled oscillator 100 according to the embodiment 1 of the present invention and the voltage applied to the same.

First, the tank circuit 5 having the first variable capacitor 4, the first inductor 2 and the second inductor 3 resonates at an oscillation frequency and has a pure resistive impedance.

Therefore, as shown in FIG. 2, a voltage “Vp1” and a current “I_{Vp1}” at one output end 14 of the tank circuit 5 are in phase with each other.

As shown in FIG. 2, the phase of a current “I_{L1}” flowing through the first inductor 2 is delayed by 0 with respect to the phase of the current “I_{Vp1}”. Furthermore, the phase of a current “I_{C1}” flowing through the first variable capacitor 4 is advanced by θ with respect to the phase of the current “I_{Vp1}”. The advance and the delay of the both currents are equal in magnitude.

A voltage “Vp2” and a current “I_{Vp2}” at a connection point 15 between the other end of the third inductor 9 and the third MOS transistor 10 are in phase with each other, and, according to the prior art that involves no second variable capacitor 13, the voltage “Vp2” and the current “I_{Vp2}”, that is, a current “I_{L2}” are in phase with each other. As a result, the current “I_{L1}” and the current “I_{L2}” are out of phase.

The mutual inductance that occurs when out-of-phase currents flow is not variable.

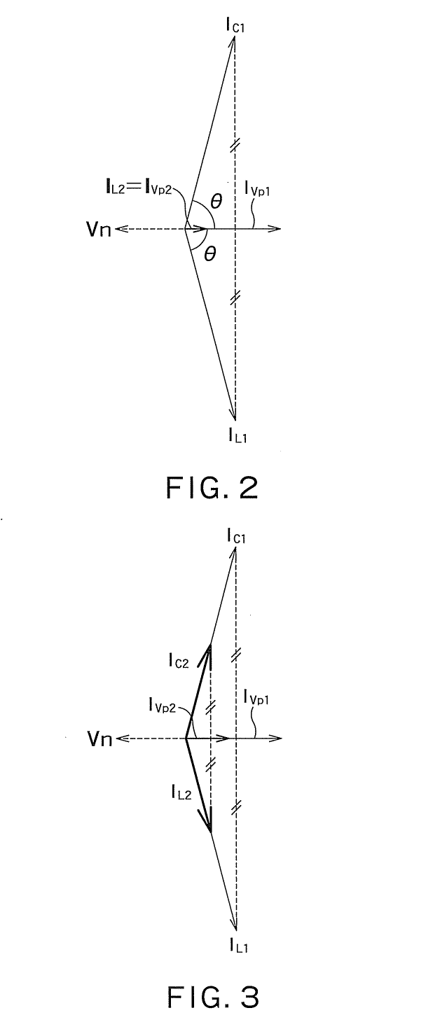

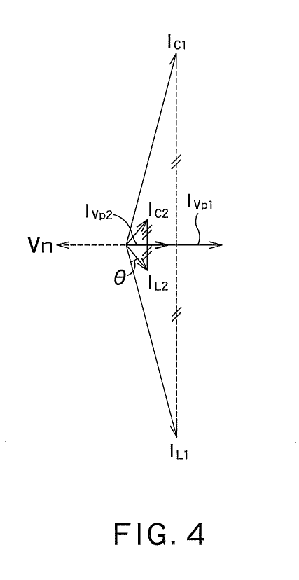

Thus, in order to make the mutual inductance variable, the voltage-controlled oscillator 100 according to this embodiment has the second variable capacitor 13 for adjusting the phase of the current “I_{L2}”. As shown in FIGS. 3 and 4, the current “I_{L2}” flowing through the third inductor 9 is delayed with respect to the current “I_{Vp2}”. In addition, a current “I_{C2}” flowing through the second variable capacitor 13 is advanced with respect to the current “I_{Vp2}”. The delay and the advance of the both currents are equal in magnitude.

As shown in FIGS. 3 and 4, by adjusting the capacitance of the second variable capacitor 13, a mutual inductance component COSθ available as a variable inductance can be adjusted (in FIG. 3, θ=0°), and the current “I_{L2}” flowing through the third inductor can be increased.

The same relationship is established at the other output end 16 of the tank circuit 5 and a connection point 17.

As described above, the phase of the current “I_{L2}”, that is, the variable component of the mutual inductance can be adjusted by adjusting the capacitance of the second variable capacitor 13. As a result, the oscillation frequency of the voltage-controlled oscillator 100 can be adjusted.

As described above, the voltage-controlled oscillator according to this embodiment can control the oscillation frequency to provide a desired frequency range.

In this embodiment, MOS transistors of the opposite conductivity type can also be used in the voltage-controlled oscillator by inverting the polarity of each circuit arrangement.

### Embodiment 2

The third and fourth MOS transistors 10 and 12 of the voltage-controlled oscillator 100 according to the embodiment 1 can be omitted. Thus, with regard to an embodiment 2, an arrangement that does not include the third and fourth MOS transistors will be described.

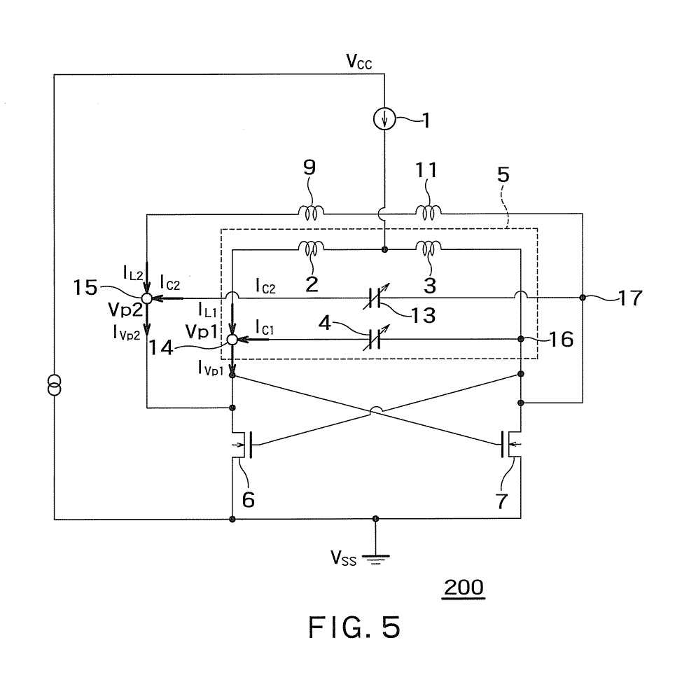

FIG. 5 is a circuit diagram showing essential parts of a voltage-controlled oscillator 200 according to the embodiment 2 of the present invention, which is an aspect of the present invention. In this drawing, the same reference numerals as those in the embodiment 1 denote the same parts as in the embodiment 1.

As shown in FIG. 5, the voltage-controlled oscillator 200 has a tank circuit 5 including a first inductor 2 that has one end connected to a power supply potential “V_{CC}” via a first current source 1, a second inductor 3 that has one end connected to the power supply potential “V_{CC}” via the first current source 1, and a first variable capacitor 4 that is connected between the other end of the first inductor 2 and the other end of the second inductor 3 and has a capacitance controlled in accordance with a first oscillation frequency controlling voltage.

In addition, the voltage-controlled oscillator 200 has a first n-type MOS transistor 6 that is connected between the other end of the first inductor 2 and a ground potential “V_{SS}” and has the gate connected to the other end of the second inductor 3 and a second n-type MOS transistor 7 that is connected between the other end of the second inductor 3 and the ground potential “V_{SS}” and has the gate connected to the other end of the first inductor 2.

In addition, the voltage-controlled oscillator 200 has a third inductor 9 that has one end connected to one output end 14 of the tank circuit 5, a fourth inductor 11 that has one end connected to the other end of the third inductor 9 and the other end connected to the other output end 16 of the tank circuit 5, and a second variable capacitor 13 that is connected between the one end of the third inductor 9 and the other end of the fourth inductor 11 and has a capacitance controlled in accordance with a second oscillation frequency controlling voltage.

As in the embodiment 1, when an operating current flows, the first inductor 2 and the third inductor 9 produce a mutual inductance. Similarly, when an operating current flows, the second inductor 3 and the fourth inductor 11 produce a mutual inductance in accordance with the phase of the operating current.

In addition, the tank circuit 5 changes the oscillation frequency of the oscillation signal when the capacitance of the first variable capacitor 4 changes with the oscillation frequency controlling voltage applied thereto. Besides, the oscillation frequency changes with the mutual inductances described above.

The principle of control of the oscillation frequency of the voltage-controlled oscillator 200 configured as described above is the same as that of the voltage-controlled oscillator according to the embodiment 1 and can be explained in the same manner with reference to the vector diagrams of FIGS. 3 and 4 described above.

As described above, the voltage-controlled oscillator according to this embodiment can control the oscillation frequency and provide a desired frequency range.

### Embodiment 3

With regard to the embodiments 1 and 2, specific configurations of the voltage-controlled oscillators have been described. With regard to an embodiment 3, an adjustment circuit for adjusting the oscillation frequency of the voltage-controlled oscillators will be described.

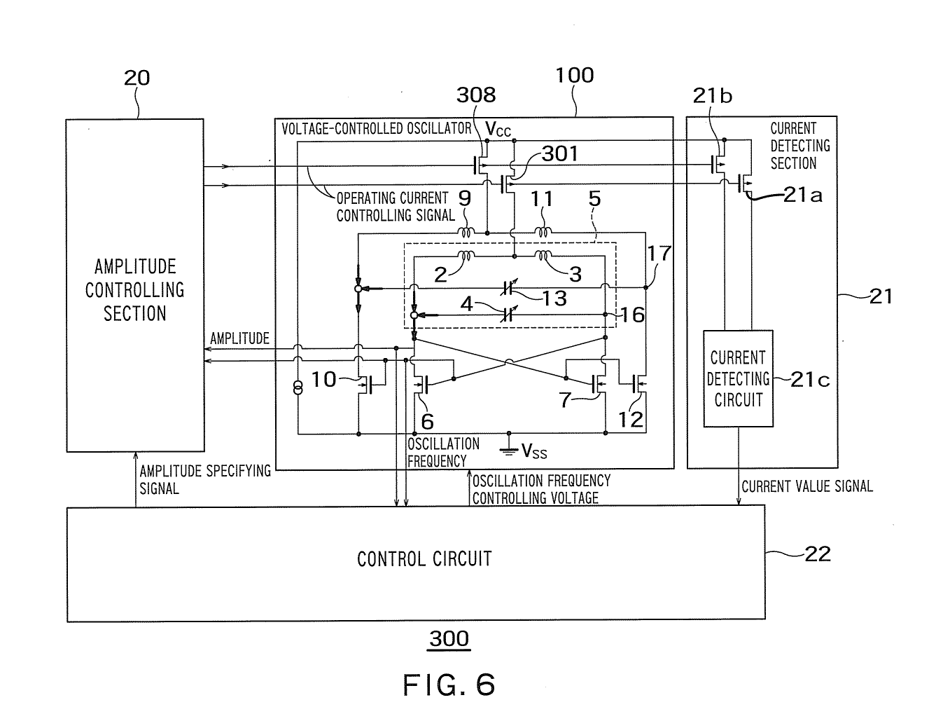

FIG. 6 is a circuit diagram showing essential parts of an adjustment circuit 300 for a voltage-controlled oscillator according to the embodiment 3 of the present invention, which is an aspect of the present invention. In this drawing, the same reference numerals as those in the embodiment 1 denote the same parts as in the embodiment 1. While FIG. 6 shows an application of the voltage-controlled oscillator 100 according to the embodiment 1, the adjustment circuit 300 can be equally applied to the voltage-controlled oscillator 200 according to the embodiment 2 as described below.

The adjustment circuit 300 for a voltage-controlled oscillator has a voltage-controlled oscillator 100 and an amplitude controlling section 20 that detects the amplitude of the oscillation signal from a tank circuit 5 and controls the amplitude of the oscillation signal from the tank circuit 5 by changing a first operating current flowing through a first inductor 2 and a second inductor 3 for operating the voltage-controlled oscillator 100 and a second operating current flowing through a third inductor 9 and a fourth inductor 11 for operating the voltage-controlled oscillator 100.

The amplitude controlling section 20 outputs an operating current controlling signal to the gates of an n-type MOS transistor 301, which serves as a first current source, and an n-type MOS transistor 308, which serves as a second current source, thereby controlling the first and second operating currents.

In the case where the adjustment circuit 300 is applied to the voltage-controlled oscillator 200 according to the embodiment 2, the n-type MOS transistor 308 serving as the second current source is omitted.

The adjustment circuit 300 for a voltage-controlled oscillator further has a current detecting section 21 for detecting the first operating current and the second operating current.

The current detecting section 21 has n-type MOS transistors 21a and 21b constituting a current source that are connected to a power supply potential “V_{CC}” and receive the operating current controlling signal described above at the respective gates, and a current detecting circuit 21c that detects the first and second operating currents flowing through the n-type MOS transistors 301 and 308, by measuring the currents flowing through the n-type MOS transistors 21a and 21b.

In the case where the adjustment circuit 300 is applied to the voltage-controlled oscillator 200 according to the embodiment 2, since the second current source is omitted, the n-type MOS transistor 21b is also omitted.

The adjustment circuit 300 for a voltage-controlled oscillator further has a control circuit 22 that controls the amplitude controlling section 20 by outputting an amplitude specifying signal for specifying the amplitude and controls the voltage-controlled oscillator 100 by outputting an oscillation frequency controlling voltage.

The control circuit 22 controls the amplitude controlling section 20 to change the first and second operating currents at a desired amplitude in accordance with the values of the operating currents (current value signals) detected by the current detecting section 21. In addition, the control circuit 22 detects the oscillation frequency of the oscillation signal from the tank circuit 5 and controls first and second oscillation frequency controlling voltages to change the capacitances of a first variable capacitor 4 and a second variable capacitor 13, thereby making the tank circuit 5 output an oscillation signal at a desired oscillation frequency.

In this way, the oscillation frequency of the voltage-controlled oscillator can be controlled, and a desired frequency range can be provided.

In addition, the control circuit 22 controls the amplitude controlling section 20 to change the first and second operating currents at a desired amplitude in accordance with the values of the operating currents detected by the current detecting section 21 in such a manner that the sum of the first operating current and the second operating current, that is, the operating current supplied to the voltage-controlled oscillator 100 is minimized.

In the case where the adjustment circuit 300 is applied to the voltage-controlled oscillator 200 according to the embodiment 2, the control circuit 22 controls the amplitude controlling section 20 to change the operating currents at a desired amplitude in such a manner that the value of the first operating current, that is, the operating current supplied to the voltage-controlled oscillator 200 is minimized.

In this way, the oscillation frequency of the voltage-controlled oscillator can be controlled, and a desired frequency range can be provided, while reducing the power consumption of the voltage-controlled oscillator.

As described above, the adjustment circuit for a voltage-controlled oscillator according to this embodiment can control the oscillation frequency of the voltage-controlled oscillator and provide a desired frequency range.

In the embodiments described above, an additional element, such as a resistor and an inductor, may be provided between the ground potential and a MOS transistor connected to the ground potential.

What is claimed is:

1. A voltage-controlled oscillator, comprising:
a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with an oscillation frequency controlling voltage;
a first MOS transistor connected between the other end of said first inductor and a ground potential and having the gate connected to the other end of said second inductor;
a second MOS transistor connected between the other end of said second inductor and said ground potential and having the gate connected to the other end of said first inductor;
a third inductor having one end connected to said power supply potential;
a third MOS transistor connected between the other end of said third inductor and said ground potential and having the gate connected to the gate of the first MOS transistor;
a fourth inductor having one end connected to said power supply potential;
a fourth MOS transistor connected between the other end of said fourth inductor and said ground potential and having the gate connected to the gate of the second MOS transistor; and
a second variable capacitor connected between the other end of said third inductor and the other end of said fourth inductor.

2. The voltage-controlled oscillator according to claim 1, wherein said first inductor and said second inductor are connected to said power supply potential via a first current source for supplying an operating current, and
said third inductor and said fourth inductor are connected to said power supply potential via a second current source for supplying an operating current.

3. A voltage-controlled oscillator, comprising:
a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with an oscillation frequency controlling voltage;
a first MOS transistor connected between the other end of said first inductor and a ground potential and having the gate connected to the other end of said second inductor;
a second MOS transistor connected between the other end of said second inductor and said ground potential and having the gate connected to the other end of said first inductor;
a third inductor having one end connected to one output end of said tank circuit;
a fourth inductor having one end connected to the other end of said third inductor and the other end connected to the other output end of the tank circuit; and
a second variable capacitor connected between the one end of said third inductor and the other end of said fourth inductor.

4. The voltage-controlled oscillator according to claim 3, wherein said first inductor and said second inductor are connected to said power supply potential via a current source for supplying an operating current.

5. An adjustment circuit for a voltage-controlled oscillator, comprising:
a voltage-controlled oscillator including: a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with a first oscillation frequency controlling voltage; a first MOS transistor connected between the other end of said first inductor and a ground potential and having the gate connected to the other end of said second inductor; a second MOS transistor connected between the other end of said second inductor and said ground potential and having the gate connected to the other end of said first inductor; a third inductor having one end connected to said power supply potential; a third MOS transistor connected between the other end of said third inductor and said ground potential and having the gate connected to the gate of the first MOS transistor; a fourth inductor having one end connected to said power supply potential; a fourth MOS transistor connected between the other end of said fourth inductor and said ground potential and having the gate connected to the gate of the second MOS transistor; and a second variable capacitor connected between the other end of said third inductor and the other end of said fourth inductor and having a capacitance controlled in accordance with a second oscillation frequency controlling voltage;
an amplitude controlling section that detects the amplitude of an oscillation signal from said tank circuit and controls the amplitude of the oscillation signal from said tank circuit by changing an operating current for operating said voltage-controlled oscillator;
a current detecting section that detects said operating current; and
a control circuit that controls said amplitude controlling section and said voltage-controlled oscillator,
wherein said control circuit controls said amplitude controlling section to change said operating current at a desired amplitude in accordance with the value of the current detected by said current detecting section, detects the oscillation frequency of the oscillation signal from said tank circuit and controls said first and second oscillation frequency controlling voltages to change the values of the capacitance of the first and second variable capacitors, thereby making said tank circuit output an oscillation signal at a desired oscillation frequency.

6. The adjustment circuit for a voltage-controlled oscillator according to claim 5, wherein said control circuit controls said amplitude controlling section to change said operating current at a desired amplitude in accordance with the value of the current detected by said current detecting section in such a manner that said operating current is minimized.

7. The adjustment circuit for a voltage-controlled oscillator according to claim 5, wherein said first inductor and said second inductor are connected to said power supply potential via a first current source for supplying an operating current, and
said third inductor and said fourth inductor are connected to said power supply potential via a second current source for supplying an operating current.

8. The adjustment circuit for a voltage-controlled oscillator according to claim 6, wherein said first inductor and said second inductor are connected to said power supply potential via a first current source for supplying an operating current, and
said third inductor and said fourth inductor are connected to said power supply potential via a second current source for supplying an operating current.

9. An adjustment circuit for a voltage-controlled oscillator, comprising: a tank circuit that has a first inductor having one end connected to a power supply potential, a second inductor having one end connected to said power supply potential, and a first variable capacitor connected between the other end of said first inductor and the other end of said second inductor and having a capacitance controlled in accordance with a first oscillation frequency controlling voltage; a first MOS transistor connected between the other end of said first inductor and a ground potential and having the gate connected to the other end of said second inductor; a second MOS transistor connected between the other end of said second inductor and said ground potential and having the gate connected to the other end of said first inductor; a third inductor having one end connected to one output end of said tank circuit; a fourth inductor having one end connected to the other end of said third inductor and the other end connected to the other output end of the tank circuit; and a second variable capacitor connected between the one end of said third inductor and the other end of said fourth inductor and having a capacitance controlled in accordance with a second oscillation frequency controlling voltage;
an amplitude controlling section that detects the amplitude of an oscillation signal from said tank circuit and controls the amplitude of the oscillation signal from said tank circuit by changing an operating current for operating said voltage-controlled oscillator;
a current detecting section that detects said operating current; and
a control circuit that controls said amplitude controlling section and said voltage-controlled oscillator,
wherein said control circuit controls said amplitude controlling section to change said operating current at a desired amplitude in accordance with the value of the current detected by said current detecting section, detects the oscillation frequency of the oscillation signal from said tank circuit and controls said first and second oscillation frequency controlling voltages to change the values of the capacitance of the first and second variable capacitors, thereby making said tank circuit output an oscillation signal at a desired oscillation frequency.

10. The adjustment circuit for a voltage-controlled oscillator according to claim 9, wherein said control circuit controls said amplitude controlling section to change said operating current at a desired amplitude in accordance with the value of the current detected by said current detecting section in such a manner that said operating current is minimized.

11. The adjustment circuit for a voltage-controlled oscillator according to claim 9, wherein said first inductor and said second inductor are connected to said power supply potential via current source for supplying an operating current.

12. The adjustment circuit for a voltage-controlled oscillator according to claim 10, wherein said first inductor and said second inductor are connected to said power supply potential via current source for supplying an operating current.
